(19) United States
(12) Patent Application Publication
(10) Pub. No.: US 2011/0188551 A1
(43) Pub. Date: Aug. 4, 2011

(54) COMMUNICATION SYSTEM COMPENSATING FREQUENCY OFFSET OF AN EXTERNAL REFERENCE CLOCK GENERATOR, COMPENSATION METHOD THEREOF AND DATA TRANSCEIVER EQUIPMENT INCLUDING THE COMMUNICATION SYSTEM

(76) Inventors: Jongshin SHIN, Anyang-si (KR); Jiyoung Kim, Osan-si (KR)

(21) Appl. No.: 12/914,246

(22) Filed: Oct. 28, 2010

(30) Foreign Application Priority Data
Jan. 29, 2010 (KR) 10-2010-0008627

(51) Int. Cl. H04B 1/38; H03L 7/08

(52) U.S. Cl. 375/219; 327/156

(57) ABSTRACT

Example embodiments are directed to a communication system including a frequency synthesizer configured to compensate a frequency error of a reference clock generator, thereby reducing the implementing cost of the reference clock generator. The communication system includes a fractional-N type frequency synthesizer and a frequency control data generation unit that measures a frequency offset value of a reference clock in a measurement mode and provides a frequency control data based on the measured frequency offset value to the frequency synthesizer, for obtaining a frequency of a preset output clock. An external reference clock generator that generates a reference clock having a relatively large frequency error may be used in the communication system, and thus the manufacturing cost of the communication system is reduced.

### CROSS-REFERENCE TO RELATED APPLICATIONS

This U.S. non-provisional patent application claims priority under 35 U.S.C. §119 to Korean Patent Application No. 10-2010-0008627, filed on Jan. 29, 2010, the entire contents of which are hereby incorporated by reference.

### BACKGROUND

Example embodiments relate to a communication system including a frequency synthesizer for generating a preset output clock, and more particularly, to a communication system including a frequency synthesizer, which can more sufficiently cover the frequency error of a reference clock generator.

A data transmission scheme of a communication system may be categorized into a synchronous transmission scheme, a mesochronous transmission scheme and a plesiochronous transmission scheme according to schemes of operating data sampling clocks that are used in a transmitter and a receiver.

For example, in the case of a communication system using the plesiochronous transmission scheme, a transmission part and a reception part may have a defined frequency offset between them. As an example, in the case of a communication system such as serial-ATA, an allowable frequency offset for an output clock, for example, a data sampling clock, is limited within ±350 ppm, except for Spread Spectrum Clocking (SSC). A majority of a frequency offset representing such a frequency error depends on an external reference clock. As a result, when a frequency offset of Δf exists in a reference clock, a frequency offset equal to Δf appears in an output clock.

With the speeding up of a data transfer rate, a reference clock generator, in which a distribution of a frequency offset is less than an allowable value, is used in a communication system, for meeting a frequency offset standard that is becoming tighter. Accordingly, an expensive crystal oscillator for generating a reference clock having a low frequency offset is required as a reference clock generator, and thus the implementing cost of a communication system increases.

### SUMMARY

According to example embodiments, a communication system, includes a fractional-N type frequency synthesizer; and a frequency control data generation unit configured to measure a frequency offset value of a reference clock, and to provide a frequency control data based on the measured frequency offset value to the frequency synthesizer, the frequency control data generation unit further configured to obtain a frequency of an output clock when a frequency offset exists in the reference clock input to the frequency synthesizer.

According to example embodiments, the frequency control data generation unit includes a clock data recovery unit configured to recover a received clock through a phase locked loop which receives a received data, and restoring the received data with the recovered clock; a frequency comparator configured to compare a frequency of the received clock and a frequency of an output clock of the frequency synthesizer to measure a frequency offset for the reference clock; and a filter configured to filter an output of the frequency comparator to output the frequency control data.

According to example embodiments, the frequency control data generation unit further includes a non-volatile storage unit storing the frequency control data; and a switching unit configured to provide the frequency control data stored in the storage unit to the frequency synthesizer in response to a switching control signal.

According to example embodiments, the frequency control data generation unit includes a clock data recovery unit restoring a received data with the output clock of the frequency synthesizer, and comparing a frequency of the output clock and a frequency of the received data; and a filter filtering an output of the clock data recovery unit to output the frequency control data.

According to example embodiments, the frequency control data generation unit further includes a non-volatile storage unit storing the frequency control data; and a switching unit configured to provide the frequency control data stored in the storage unit to the frequency synthesizer in response to a switching control signal.

According to example embodiments, the frequency control data generation unit includes a frequency comparator comparing a frequency of the output clock of the frequency synthesizer and a frequency of a test reception data which is applied in a measurement mode, for measuring a frequency offset for the reference clock; and a filter filtering an output of the frequency comparator to generate the frequency control data.

According to example embodiments, the frequency control data generation unit further includes a non-volatile storage unit storing the frequency control data; and a switching unit configured to provide the frequency control data stored in the storage unit to the frequency synthesizer in response to a switching control signal.

According to example embodiments, the frequency synthesizer includes a sigma-delta modulator configured to generate a scaling control signal in response to the frequency control data; and a fractional-N phase locked loop including a divider, the divider variably dividing the output clock in response to the scaling control signal, and multiplying the reference clock to generate the output clock.

According to example embodiments, the fractional-N phase locked loop includes a phase frequency detector configured to compare the reference clock and a feedback clock of the output clock to generate a phase difference detection signal; a charge pump configured to generate a pump output in response to the phase difference detection signal of the phase frequency detector; a loop filter low-pass configured to filter the pump output of the charge pump to output a variable control voltage; a voltage control oscillator configured to generate the output clock in response to the variable control voltage of the loop filter; and a divider configured to output the feedback clock by variably dividing the output clock in response to the scaling control signal.

According to example embodiments, the sigma-delta modulator includes a plurality of accumulators connected in series with each other, at least one accumulator receiving the frequency control data and a carry bit of the plurality of accumulators being input to a differencer, and an encoding unit configured to output the scaling control signal in response to an output of the differencer.

According to example embodiments, the divider includes a switching unit configured to switch the output clock between a plurality of dividing units in response to a mode control signal from a control unit; a selector configured to selectively output an output of the plurality of dividing units in response to the mode control signal from the control unit; and the control unit configured to output the mode control signal to the switching unit and the selector in response to the scaling control signal.

According to example embodiments, a method of controlling a fractional-N type frequency synthesizer which receives a reference clock to generate an output clock includes measuring a frequency offset value of the reference clock input to the frequency synthesizer to obtain a frequency of an output clock when the frequency offset exists in the reference clock, the frequency offset value being based on temperature; and applying a frequency control data based on the measured frequency offset value to the frequency synthesizer.

According to example embodiments, the method further includes generating a scaling control signal using a sigma-delta modulator of the frequency synthesizer, the scaling control signal variably dividing the output clock in response to the frequency control data.

According to example embodiments, the method further includes applying the scaling control signal to a divider, the divider configuring a fractional-N phase locked loop of the frequency synthesizer to provide the output clock a preset multiplication clock, the frequency offset of the reference clock being corrected.

According to example embodiments, the method further includes storing the frequency control data based on the measured frequency offset value.

According to example embodiments, a data transceiver includes the fractional-N type frequency synthesizer.

According to example embodiments, a data transceiver equipment includes the data transceiver.

According to example embodiments, the data transceiver equipment includes a temperature sensor configured to measure a temperature.

According to example embodiments, the method further includes obtaining the frequency control data by comparing a frequency of the output clock of the frequency synthesizer and a frequency of a received data obtained from a clock data recovery unit and filtering a result of the comparison, the received data being restored.

According to example embodiments, a data transceiver equipment includes a data transceiver including the communication system according to example embodiments; a temperature sensor to sense a temperature, the temperature sensor being near a reference clock generator that is configured to generate the reference clock; a storage unit configured to store the frequency control data corresponding to a temperature sensing data output from the temperature sensor; and a controller configured to output a frequency control data from the storage unit to the frequency synthesizer during operation of the data transceiver, the frequency control data corresponding to a temperature sensing data currently measured.

According to example embodiments, the storage unit is a flash memory which stores the frequency control data in a non-volatile fashion.

According to example embodiments, the frequency synthesizer includes a sigma-delta modulator configured to generate a scaling control signal in response to the frequency control data, the sigma-delta modulator configured to compensate the frequency offset of the reference clock; and a fractional-N phase locked loop including a divider performing fractional division on the output clock in response to the scaling control signal, and multiplying the reference clock to generate the output clock, wherein the frequency offset of the reference clock is compensated.

### BRIEF DESCRIPTION OF THE DRAWINGS

The above and other features and advantages will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram illustrating a communication system according to example embodiments of the inventive concepts;

FIG. 2 illustrates an example of a frequency synthesizer of FIG. 1;

FIG. 3 illustrates an example of a sigma-delta modulator of FIG. 2;

FIG. 4 illustrates an example of a divider of FIG. 2;

FIG. 5 is a diagram illustrating an example of a phase frequency detector of FIG. 2;

FIG. 6 is a diagram illustrating an example of a clock data recovery unit of FIG. 1;

FIG. 7 is a block diagram illustrating a communication system according to example embodiments of the inventive concepts;

FIG. 8 is a block diagram illustrating a communication system according to example embodiments of the inventive concepts; and

FIG. 9 is a block diagram illustrating data transceiver equipment including a communication system according to example embodiments of the inventive concepts.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate fauns and should not be construed as limited to only the embodiments set forth herein.

Accordingly, while example embodiments are capable of various modifications and alternative fauns, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

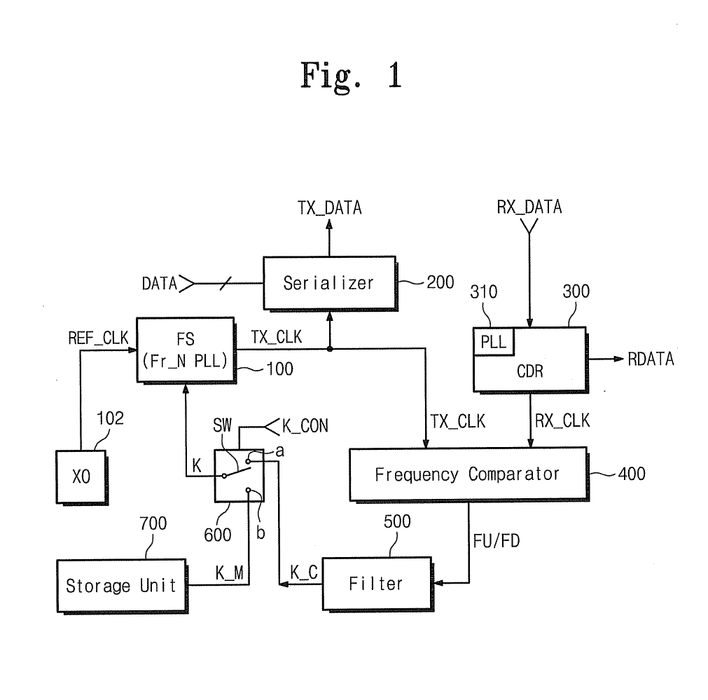

FIG. 1 is a block diagram illustrating a communication system according to example embodiments of the inventive concepts.

Referring to FIG. 1, a communication system according to example embodiments of the inventive concepts includes a fractional-N type frequency synthesizer 100, and a frequency control data generation unit 300, 400 and 500.

For allowing a frequency of a preset output clock TX_CLK to be obtained even when a frequency offset exists in a reference clock REF_CLK applied to the frequency synthesizer 100, the frequency control data generation unit 300, 400 and 500 measures a frequency offset value of the reference clock REF_CLK and provides a frequency control data K based on the measured frequency offset value to the frequency synthesizer 100.

In FIG. 1, the frequency control data generation unit may include a clock data recovery unit 300, a frequency comparator 400, and a filter 500. Herein, the clock data recovery unit 300 recovers a received clock RX_CLK through a Phase Locked Loop (PLL) 310 that receives a received data RX_DATA and restores the received data RX_DATA with the recovered clock RX_CLK. The frequency comparator 400 compares a frequency of the received clock RX_CLK and a frequency of the output clock TX_CLK of the frequency synthesizer 100 for measuring a frequency offset of the reference clock REF_CLK. The filter 500 filters an output FU/FD of the frequency comparator 400 to output the frequency control data K.

Additionally, the frequency control data generation unit may include a storage unit 700 and a switching unit 600. Herein, the storage unit 700 stores the frequency control data K in a non-volatile manner. The switching unit 600 provides the frequency control data K, which is stored in the storage unit 700, to the frequency synthesizer 100 in response to a switching control signal K_CON.

In the case of FIG. 1, the communication system may apply a low-cost reference clock generator 102 having a relatively large frequency offset. This is because the frequency control data generation unit applies the frequency control data K for compensating the frequency offset of the reference clock REF_CLK to the fractional-N type frequency synthesizer 100. Accordingly, the manufacturing cost of the communication system is reduced.

As a result, by measuring the frequency offset value of the reference clock REF_CLK and allowing compensation to be performed by the measured frequency offset value, the communication system can obtain the output clock TX_CLK having a frequency offset within a defined maximum allowable value even when a frequency offset equal to or greater than the maximum allowable value of a specific communication standard exists in the reference clock REF_CLK applied to the frequency synthesizer 100.

In this way, when compensating the frequency offset of the reference clock REF_CLK, the reference clock generator 102 capable of being implemented with a crystal oscillator may be used in the communication system at lower cost.

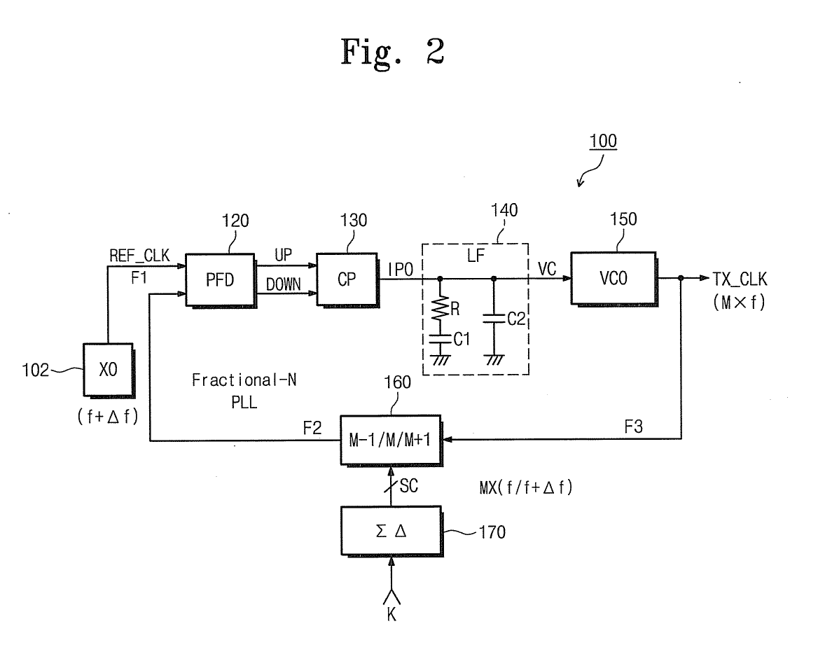

The fractional-N type frequency synthesizer 100 is illustrated in more detail in FIG. 2.

Referring to FIG. 2 that illustrates an example of the frequency synthesizer of FIG. 1, the detailed configuration of the frequency synthesizer including a fractional-N PLL and a sigma-delta modulator 170 is illustrated.

In FIG. 2, the sigma-delta modulator 170 generates a scaling control signal SC in response to the frequency control data K. Herein, the scaling control signal SC is one that is used to control the division ratio of the divider 160.

The fractional-N PLL includes a divider 160 that variably divides the output clock TX_CLK in response to the scaling control signal SC, and multiplies the reference clock REF_CLK to generate the output clock TX_CLK.

In FIG. 2, the fractional-N PLL includes a Phase Frequency Detector (PFD) 120, a Charge Pump (CP) 130, a Loop Filter (LF) 140, a Voltage Control Oscillator (VCO) 150, and a divider 160.

The phase frequency detector 120 compares the reference clock REF_CLK:F1 and the feedback clock F2 of the output clock to generate a phase difference detection signal UP/DOWN.

The charge pump 130 generates a pumping output IPO in response to the phase difference detection signal UP/DOWN of the phase frequency detector 120. Herein, the pumping output IPO may be a current that is generated by the charge or discharge operation of the charge pump 130.

The loop filter 140 low-pass filters the pumping output IPO of the charge pump 130 to output a variable control voltage VC. Herein, the variable control voltage VC is one that is obtained by integrating the pumping output IPO with a resistor R or capacitors C1 and C2.

The voltage control oscillator 150 oscillates in response to the variable control voltage VC of the loop filter 140 and thereby allows the output clock TX_CLK to be generated.

The divider 160 variably divides the output clock TX_CLK:F3 in response to the scaling control signal SC and thereby outputs the feedback clock F2.

In the communication system of FIG. 1 including the frequency synthesizer 100 of FIG. 2, the frequency offset of the output clock TX_CLK satisfies a set specification, and the frequency offset of the reference clock generator 102 is more tolerable, thereby reducing the implementing cost of the reference clock generator 102.

For this, by applying the fractional-N PLL in the frequency synthesizer 100, the frequency offset of the reference clock is compensated. For example, it is assumed that the output clock TX_CLK of the frequency synthesizer 100 functioning as a Clock Multiplication Unit (CMU) has a frequency of about 1.5 GHz and the reference clock REF_CLK outputs a frequency of “25 MHz+10000 ppm (an offset frequency: Δf)”. In this case, since the reference clock REF_CLK actually has about 25.25 MHz, a multiplying operation is not performed by about 1.5 GHz/25 MHz times but is performed by about 1.5 GHz/25.25 MHz times in the fractional-N PLL, the frequency of the output clock TX_CLK is generated as about 1.5 GHz.

In other words, when the divider 160 of FIG. 2 adds an offset frequency ‘Δf’ of the reference clock REF_CLK to the frequency of the reference clock REF_CLK and divides it, since the output clock TX_CLK appears as a frequency of “M (multiplication ratio)×f (a defined frequency of the reference clock)”, the offset frequency ‘Δf’ of the reference clock REF_CLK is removed from the output clock TX_CLK. Like in the above-described example embodiments, the multiplying operation that is performed by about 1.5 GHz/25.25 MHz times is controlled with the frequency control data K. As a result, when the scaling control signal SC is generated depending on the frequency control data K, the divider 160 divides the output clock F3 at a fractional division ratio in response to the scaling control signal SC.

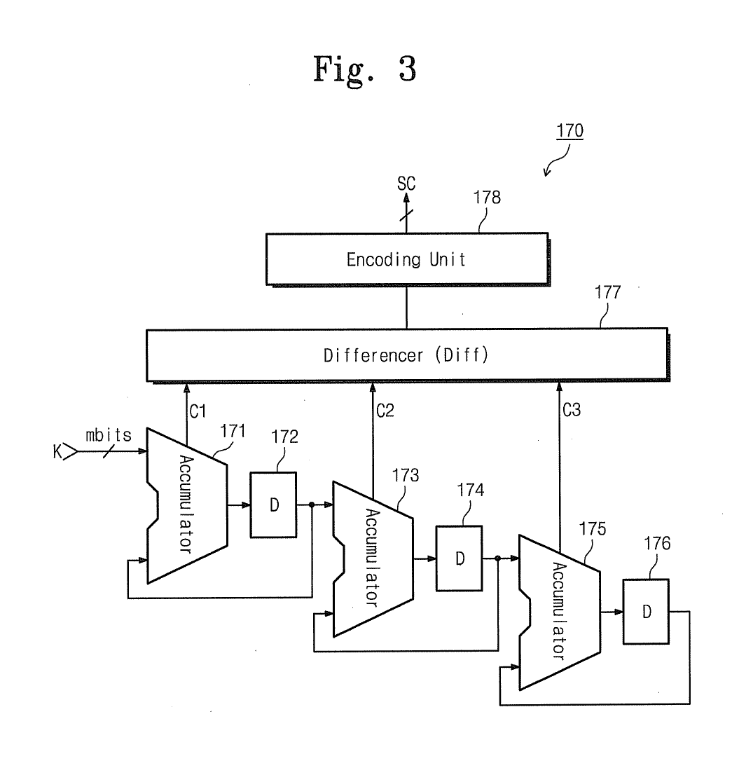

An example of the sigma-delta modulator 170, which generates the scaling control signal SC in response to the frequency control data K, is illustrated in FIG. 3.

FIG. 3 illustrates an example of the sigma-delta modulator of FIG. 2. In FIG. 3, the sigma-delta modulator 170 includes a three-stage accumulator block including accumulators 171, 173 and 175, and delays 172, 174 and 176. Moreover, the sigma-delta modulator 170 includes a differencer 177 and an encoding unit 178, for providing the scaling control signal SC to the divider 160.

When the frequency control data K is applied to the accumulator 171 as m bits (where m is a natural number equal to or greater than two), the outputs C1 to C3 of the carry bit (MSB) of the each accumulator 171, 173 and 175 are applied to the differencer 177. Herein, the m bits are set in correspondence with the bit size of the each accumulator 171, 173 and 175.

According to example embodiments of the inventive concepts, the sigma-delta modulator 170 is configured with the three-stage accumulator block, but it is not limited thereto and the number of accumulator blocks may be added or subtracted. Moreover, another type of modulator may be applied.

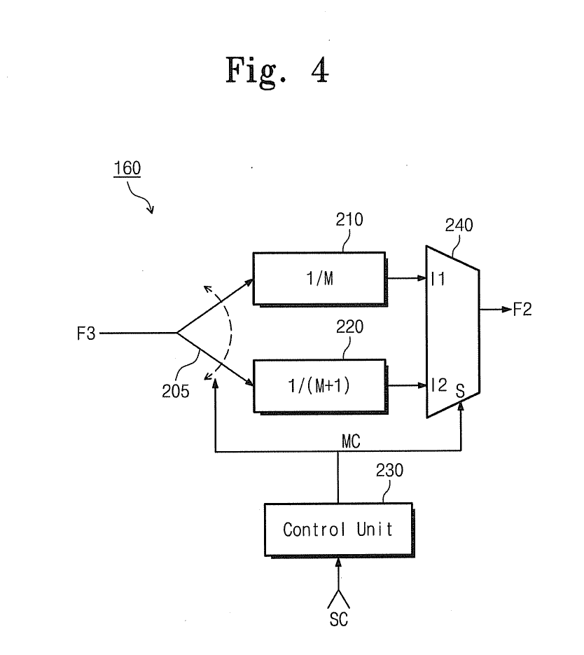

FIG. 4 illustrates an example of the divider of FIG. 2.

Referring to FIG. 4, the divider 160 includes a switching unit 205, a first dividing unit 210, a second dividing unit 220, a control unit 230, and a selector 240.

As a result, the divider 160 has a plurality of division ratios according to the scaling control signal SC that is applied to the sigma-delta modulator 170 for fractional-N frequency synthesis.

The control unit 230 generates a mode control signal MC in response to the scaling control signal SC.

The switching unit 205 switches the output clock TX_CLK to one of the first and second dividers 210 and 220 in response to the mode control signal MC that is applied from the control unit 230. If M is 59, the first divider 210 is one having a division ratio of 59, and the second divider 220 is one having a division ratio of 60.

The selector 240 selects one of the output signals of the first and second dividers 210 and 220 in response to the mode control signal MC that is applied to a selection port S. The output F2 of the selector 240 is applied to the phase frequency detector 120 of FIG. 2.

On the assumption of that the division ratio of the divider 160 is 60 (where 1.5 GHz/25 MHz=60), if nine of ten-time dividing operations divide a frequency at a division ratio of 60 and another dividing operation divides a frequency at a division ratio of 59, the dividing operation is performed at a division ratio of 59.9. The output clock TX_CLK, in which the offset frequency ‘Δf’ of the reference clock REF_CLK has been compensated by the fractional dividing operation of the divider 160, is generated in the frequency synthesizer 100, and thus a low cost oscillator 102 can be used as a reference clock generator.

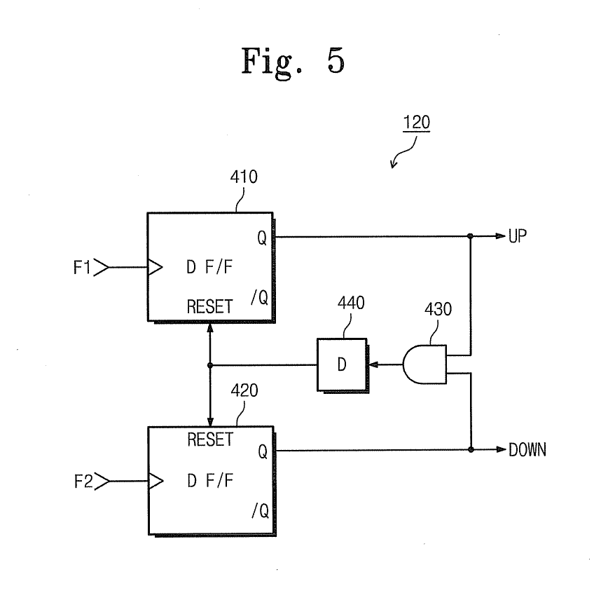

FIG. 5 is a diagram illustrating an example of the phase frequency detector of FIG. 2.

Referring to FIG. 5, the phase frequency detector 120 includes D flip-flops 410 and 420 that have reset ports RESET, an AND gate 430 that receives the phase difference detection signal UP/DOWN to generate an AND response, and a delay 440 that delays the gating output of the AND gate 430 for a certain time to apply a reset signal to the reset port RESET. The phase difference detection signal UP/DOWN, which is output from each of the output ports Q of the D flip-flops 410 and 420, is also applied to the charge pump 130 of FIG. 2. According to example embodiments of the inventive concepts, the circuit configuration of FIG. 5 is disclosed as an example of the phase frequency detector, but it is not limited thereto and another circuit configuration may be disclosed as that of the phase frequency detector.

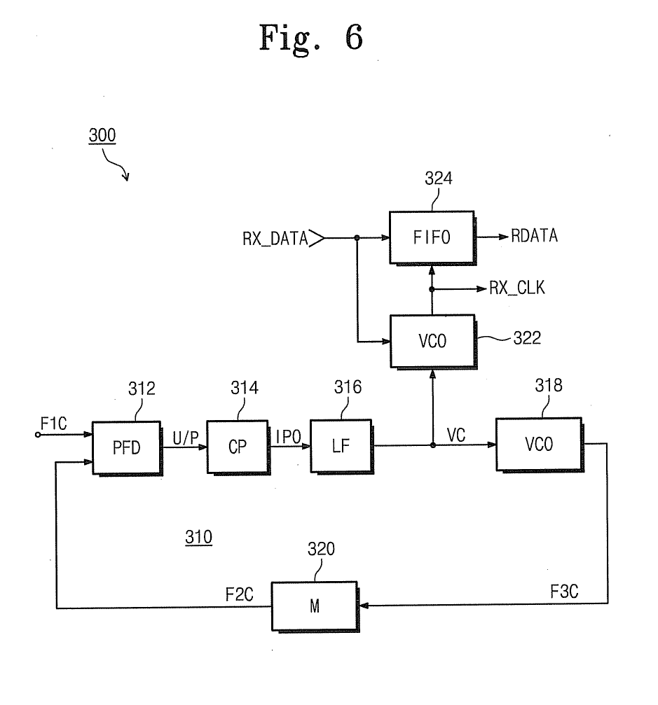

FIG. 6 is a diagram illustrating an implemented example of the clock data recovery unit of FIG. 1.

According to example embodiments of the inventive concepts, the clock data recovery unit 300 is a circuit block configuring a portion of the frequency control data generation unit, and provides the received clock RX_CLK that has been recovered. As a result, a circuit block that has been already implemented is used for measuring the frequency offset of the reference clock without adding separate hardware to the equipment. Referring to FIG. 6, similar to FIG. 2, the clock data recovery unit 300 includes the PLL 310 that is configured with the phase frequency detector 312, the charge pump 314, the loop filter 316, the first voltage control oscillator 318, the second voltage control oscillator 322 and the divider 320.

A First-In, First-Out (FIFO) memory 324 stores the received data RX_DATA and outputs a restored data RDATA, in response to the received clock RX_CLK that is output from the second voltage control oscillator 322. Herein, in the case of a normal operation, the restored data RDATA is the same data as a transmitted data TX_DATA.

According to example embodiments of inventive concepts, the received clock RX_CLK that is output from the second voltage control oscillator 322 is used. The received clock RX_CLK is applied to the frequency comparator 400 of FIG. 1 and is compared with the output clock TX_CLK. As a result, the output FU/FD of the frequency comparator 400 of FIG. 1 illustrates the frequency offset of the reference clock REF_CLK, and thus the frequency control data K is generated by filtering the output FU/FD.

Herein, since the frequency offset of the reference clock REF_CLK is not a known value but is a value based on the characteristic of an element, it varies for each reference clock generator. Therefore, in an example of FIG. 1, a degree of frequency offset is measured with the frequency comparator 400 and the filter 500. In this way, since the measured frequency offset does not frequently vary, the storage unit 700 of FIG. 1 may store a frequency offset value. As a result, if a frequency offset is measured once with a test data having an accurate frequency in a measurement mode and is stored in the storage unit 700 such as a flash memory for storing data in an initial stage of configuring the communication system, the output K_M of the storage unit 700 is permanently provided as the frequency control data K. The switching unit 600 switches a switch SW to a first selection input port ‘a’ in response to the switching control signal K_CON in the measurement mode. Consequently, the output K_C of the filter 500 is provided as the frequency control data K. When an operation of the measurement mode is terminated, the switching unit 600 switches a switch SW to a second selection input port ‘b’ in response to the switching control signal K_CON. Accordingly, the output K_M of the storage unit 700 is provided as the frequency control data K. The filter 500 may be implemented with an accumulator, for example, and is a circuit block for obtaining an average value.

The frequency control data K that is stored in the non-volatile storage unit 700 may be permanently used for compensating the frequency offset of the reference clock until the reference clock generator is replaced. When the operation of the measurement mode of the communication system is terminated and a normal operation, for example, a power-up operation is performed, the above-described frequency comparing operation is not required, and the frequency control data K_M stored in the storage unit 700 is used as the frequency control data K.

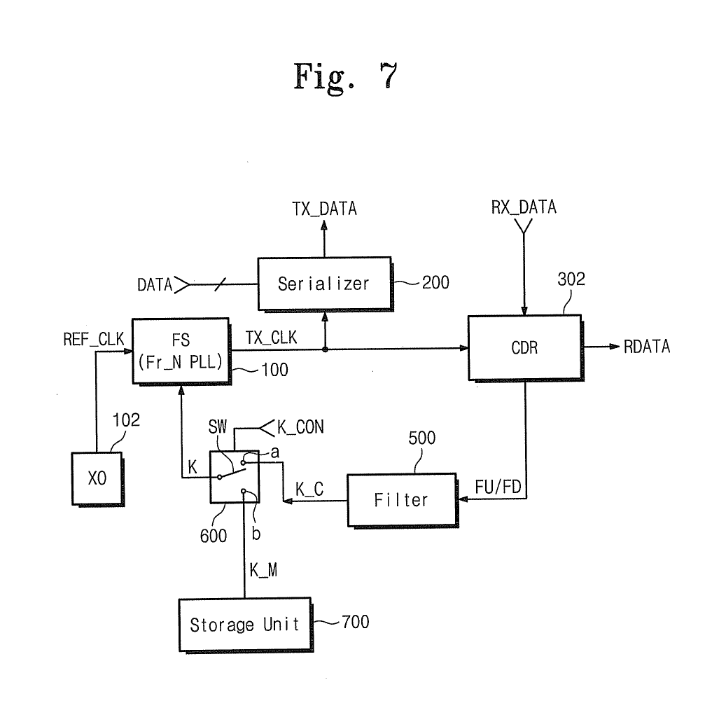

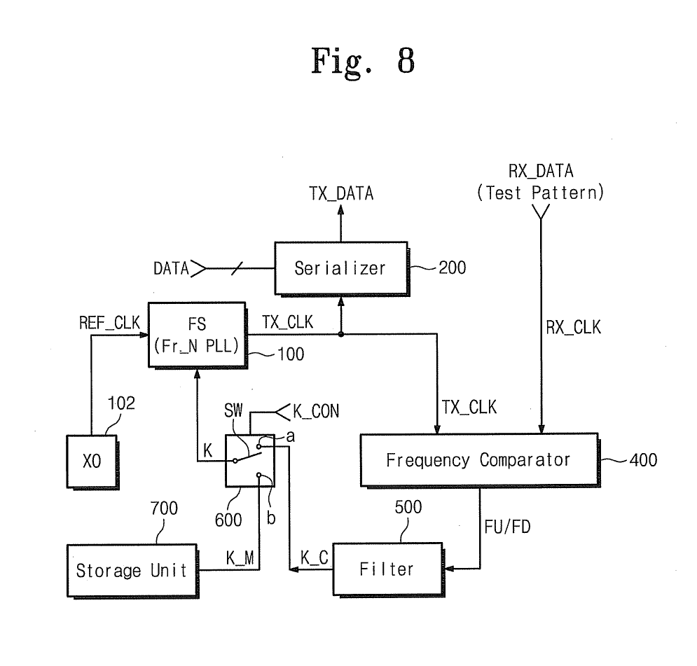

According to example embodiments of the inventive concepts described above with reference to FIG. 1, the frequency control data generation unit is configured with the clock data recovery unit 300 including the PLL 310, the frequency comparator 400 and the filter 500. However, the frequency control data generation unit may be implemented in various types like FIGS. 7 and 8.

FIG. 7 is a block diagram illustrating a communication system according to example embodiments of the inventive concepts. FIG. 8 is a block diagram illustrating a communication system according to example embodiments of the inventive concepts.

Referring to FIG. 7, an example of a frequency control data generation unit, which is configured with a clock data recovery unit 302, a filter 500, a storage unit 700 and a switching unit 600, is shown.

The clock data recovery unit 302 receives an output clock TX_CLK of the frequency synthesizer 100 as a received clock and restores a received data RX_DATA into a transmitted data TX_DATA. The clock data recovery unit 302 compares a frequency of the output clock TX_CLK and a frequency of the received data RX_DATA.

The filter 500 filters the compared output FU/FD of the clock data recovery unit 302 to output a frequency control data K_C.

The storage unit 700 stores the frequency control data K_M in a non-volatile manner.

The switching unit 600 provides the frequency control data K, which is stored in the storage unit 700, to the frequency synthesizer 100 in response to a switching control signal K_CON in a normal operation.

The frequency synthesizer 100 generates an output clock TX_CLK in which a frequency offset of a reference clock REF_CLK has been compensated according to the frequency control data K. Therefore, the reference clock generator 102 that is configured with a crystal oscillator may be implemented at lower cost.

In the case of FIG. 7, the clock data recovery unit 302 is configured as an oversampling CDR or a phase interpolator CDR. As a result, when a serializer 200 and an RX CDR 302 are driven with one frequency synthesizer 100, the CDR 302 automatically compares a frequency of the output clock TX_CLK and a frequency of the received data RX_DATA that is received, and thus the compared output FU/FD can be obtained.

Referring to FIG. 8, an example of a frequency control data generation unit, which is configured with a frequency comparator 400, a filter 500, a storage unit 700 and a switching unit 600, is shown.

The frequency comparator 400 compares a frequency of the output clock TX_CLK of the frequency synthesizer 100 and a frequency of a test reception data RX_DATA for measuring a frequency offset for the reference clock REF_CLK.

The filter 500 filters an output FU/FD of the frequency comparator 400 to output a frequency control data K_C.

The storage unit 700 stores the frequency control data K_M in a non-volatile manner.

The switching unit 600 provides the frequency control data K_M, which is stored in the storage unit 700, to the frequency synthesizer 100 as a frequency control data K in response to a switching control signal K_CON in a normal operation.

In the case of FIG. 8, the received data RX_DATA may not be applied as common data, but as a test pattern for measuring a frequency offset of a reference clock in a test mode of the communication system. As a result, if data of 0 and data of 1 are alternately applied, they become a test clock, for example.

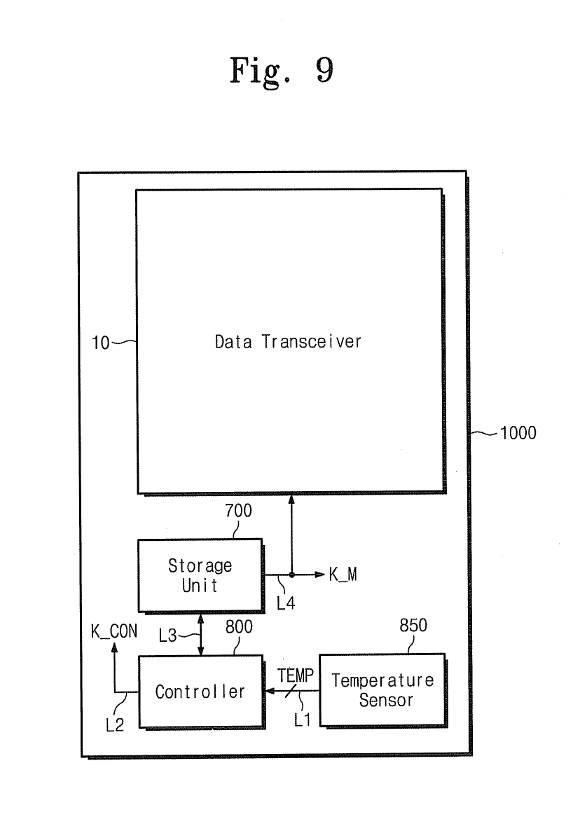

In the cases of FIGS. 1, 7 and 8, for more accurately compensating the frequency offset of the reference clock, a temperature sensor may be included like in FIG. 9.

FIG. 9 is a block diagram illustrating data transceiver equipment including a communication system according to example embodiments of the inventive concepts.

Referring to FIG. 9, data transceiver equipment 1000 may include a data transceiver 10, a temperature sensor 850, a storage unit 700, and a controller 800.

The data transceiver 10 serves as a data transceiver. As shown in example embodiments of the inventive concepts, for allowing a frequency of a preset output clock to be obtained when a fractional-N type frequency synthesizer exists and a frequency offset exists in a reference clock applied to the frequency synthesizer, the data transceiver 10 may include a frequency control data generation unit that measures a frequency offset value of the reference clock and generates a frequency control data based on the measured frequency offset value. In this case, the storage unit 700 in FIGS. 1, 7 and 8 is not included in the data transceiver 10 and is disposed in the data transceiver equipment 1000.

The temperature sensor 850 may be implemented as a semiconductor temperature sensor, and is disposed near the reference clock generator 102, that generates the reference clock REF_CLK, to sense an actual temperature.

The storage unit 700 stores the frequency change rates of the reference clock REF_CLK, which is changed according to a temperature, in a lookup table type. For example, when a frequency change rate at 25° C. is 0, a frequency change rate at 50° C. is stored as +0.5%, and a frequency change rate at 100° C. is stored as +1%. Accordingly, when a temperature measured by the temperature sensor 850 is 50° C. in a power-on operation, the frequency control data K_M for controlling the +0.5% is output from the storage unit 700.

The controller 800 allows the frequency control data K_M, corresponding to a temperature sensing data that has been measured, to be output from the storage unit 700 and to be input to the frequency synthesizer of the data transceiver 10 when the data transceiver 10 performs a normal operation. For this, the controller 800 receives the temperature sensing data TEMP of the temperature sensor 850 through a line L1 and controls the storage unit 700 through a line L3. Moreover, the controller 800 outputs the switching control signal K_CON through a line L2.

Accordingly, if the storage unit 700 receives a command indicating the output of the frequency control data K_M that is stored in response to a temperature of 50° C. through the line L3, a corresponding storage region among the storage regions of the lookup table in the storage unit 700 is accessed. Therefore, the frequency control data K_M for controlling a frequency at a change rate of +0.5% is output through a line L4 of the storage unit 700. The data transceiver 10 is connected to the line L4. In the case of the configuration of FIG. 9, since an influence by a temperature is reflected in the frequency offset of the reference clock, a frequency offset can be more accurately compensated.

In this way, although a frequency of an external reference clock is deviated from a defined standard, an output of equipment satisfies a frequency of a standard when undergoing a one-time compensating operation. In this case, accordingly, a reference clock generator having a relatively large frequency error can be used, and thus the total costs of a system are reduced.

According to example embodiments of the inventive concepts, as described above, an external reference clock generator for generating a reference clock having a relatively large frequency error may be used in the communication system, and thus the manufacturing costs of the communication system and equipment including the same are reduced.

In example embodiments of the inventive concepts, the above description is directed to the compensating of the frequency offset of the reference clock generator that provides the reference clock to a frequency synthesizer of a transmission side, but it is not limited thereto. Even when a reference clock generator of a reception side has a frequency offset, the above example embodiments of the inventive concepts may be used.

According to example embodiments of the inventive concepts, the external reference clock generator for generating the reference clock having a relatively large frequency error can be used in the communication system, and thus the manufacturing cost of the communication system is reduced.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A communication system, comprising:
a fractional-N type frequency synthesizer; and
a frequency control data generation unit configured to measure a frequency offset value of a reference clock, and to provide a frequency control data based on the measured frequency offset value to the frequency synthesizer, the frequency control data generation unit further configured to obtain a frequency of an output clock when a frequency offset exists in the reference clock input to the frequency synthesizer.

2. The communication system of claim 1, wherein the frequency control data generation unit comprises:
a clock data recovery unit configured to recover a received clock using a phase locked loop, the clock data recovery unit receiving a received data, and further configured to restore the received data with the recovered clock;
a frequency comparator configured to compare a frequency of the received clock and a frequency of the output clock of the frequency synthesizer to measure a frequency offset for the reference clock; and
a filter configured to filter an output of the frequency comparator to output the frequency control data.

3. The communication system of claim 2, wherein the frequency control data generation unit further comprises:
a non-volatile storage unit storing the frequency control data; and
a switching unit configured to provide the frequency control data stored in the storage unit to the frequency synthesizer in response to a switching control signal.

4. The communication system of claim 1, wherein the frequency control data generation unit comprises:
a clock data recovery unit restoring a received data with the output clock of the frequency synthesizer, and comparing a frequency of the output clock and a frequency of the received data; and
a filter filtering an output of the clock data recovery unit to output the frequency control data.

5. The communication system of claim 4, wherein the frequency control data generation unit further comprises:
a non-volatile storage unit storing the frequency control data; and
a switching unit configured to provide the frequency control data stored in the storage unit to the frequency synthesizer in response to a switching control signal.

6. The communication system of claim 1, wherein the frequency control data generation unit comprises:
a frequency comparator comparing a frequency of the output clock of the frequency synthesizer and a frequency of a test reception data which is applied in a measurement mode, for measuring a frequency offset for the reference clock; and
a filter filtering an output of the frequency comparator to generate the frequency control data.

7. The communication system of claim 6, wherein the frequency control data generation unit further comprises:
a non-volatile storage unit storing the frequency control data; and
a switching unit configured to provide the frequency control data stored in the storage unit to the frequency synthesizer in response to a switching control signal.

8. The communication system of claim 1, wherein the frequency synthesizer comprises:
a sigma-delta modulator configured to generate a scaling control signal in response to the frequency control data; and
a fractional-N phase locked loop including a divider, the divider variably dividing the output clock in response to the scaling control signal, and multiplying the reference clock to generate the output clock.

9. The communication system of claim 8, wherein the fractional-N phase locked loop comprises:
a phase frequency detector configured to compare the reference clock and a feedback clock of the output clock to generate a phase difference detection signal;
a charge pump configured to generate a pump output in response to the phase difference detection signal of the phase frequency detector;
a loop filter low-pass configured to filter the pump output of the charge pump to output a variable control voltage;
a voltage control oscillator configured to generate the output clock in response to the variable control voltage of the loop filter; and
a divider configured to output the feedback clock by variably dividing the output clock in response to the scaling control signal.

10. The communication system of claim 8, wherein the sigma-delta modulator comprises:
a plurality of accumulators connected in series with each other, at least one accumulator receiving the frequency control data and a carry bit of the plurality of accumulators being input to a differencer, and
an encoding unit configured to output the scaling control signal in response to an output of the differencer.

11. The communication system of claim 8, wherein the divider comprises:
a switching unit configured to switch the output clock between a plurality of dividing units in response to a mode control signal from a control unit;
a selector configured to selectively output an output of the plurality of dividing units in response to the mode control signal from the control unit; and
the control unit configured to output the mode control signal to the switching unit and the selector in response to the scaling control signal.

12. A method of controlling a fractional-N type frequency synthesizer which receives a reference clock to generate an output clock, the method comprising:
measuring a frequency offset value of the reference clock input to the frequency synthesizer to obtain a frequency of an output clock when the frequency offset exists in the reference clock, the frequency offset value being based on temperature; and
applying a frequency control data based on the measured frequency offset value to the frequency synthesizer.

13. The method of claim 12, further comprising:
generating a scaling control signal using a sigma-delta modulator of the frequency synthesizer, the scaling control signal variably dividing the output clock in response to the frequency control data.

14. The method of claim 13, further comprising:
applying the scaling control signal to a divider, the divider configuring a fractional-N phase locked loop of the frequency synthesizer to provide the output clock a preset multiplication clock, the frequency offset of the reference clock being corrected.

15. The method of claim 13, further comprising:
storing the frequency control data based on the measured frequency offset value.

16. The method of claim 13, wherein a data transceiver includes the fractional-N type frequency synthesizer.

17. The method of claim 16, wherein a data transceiver equipment includes the data transceiver.

18. The method of claim 17, wherein the data transceiver equipment includes a temperature sensor configured to measure a temperature.

19. The method of claim 18, further comprising:
obtaining the frequency control data by comparing a frequency of the output clock of the frequency synthesizer and a frequency of a received data obtained from a clock data recovery unit and filtering a result of the comparison, the received data being restored.

20. A data transceiver equipment, comprising:
a data transceiver including the communication system of claim 1;
a temperature sensor to sense a temperature, the temperature sensor being near a reference clock generator that is configured to generate the reference clock;
a storage unit configured to store the frequency control data corresponding to a temperature sensing data output from the temperature sensor; and
a controller configured to output a frequency control data from the storage unit to the frequency synthesizer during operation of the data transceiver, the frequency control data corresponding to a temperature sensing data currently measured.

21. The data transceiver equipment of claim 20, wherein the storage unit is a flash memory which stores the frequency control data in a non-volatile fashion.

22. The data transceiver equipment of claim 20, wherein the frequency synthesizer comprises:
a sigma-delta modulator configured to generate a scaling control signal response to the frequency control data, the sigma-delta modulator configured to compensate the frequency offset of the reference clock; and
a fractional-N phase locked loop including a divider performing fractional division on the output clock in response to the scaling control signal, and multiplying the reference clock to generate the output clock, wherein the frequency offset of the reference clock is compensated.
